(19) United States
(12) Patent Application Publication
(10) Pub. No.: US 2025/0277821 A1
(43) Pub. Date: Sep. 4, 2025

(54) HIGH VOLTAGE SOLID INSULATED CAPACITIVE-RESISTIVE DIVIDER

(71) Applicant: Hubbell Incorporated, Shelton, CT (US)

(72) Inventor: Dragan D. Tabakovic, Clearwater, FL (US)

(21) Appl. No.: 19/068,063

(22) Filed: Mar. 3, 2025

Related U.S. Application Data
(60) Provisional application No. 63/560,207, filed on Mar. 1, 2024.

(51) Int. Cl. G01R 15/16; G01R 15/06

(52) U.S. Cl. CPC G01R 15/16; G01R 15/06

(57) ABSTRACT

A capacitive voltage divider designed to step down high-voltage from an electrical power line to a lower more suitable voltage includes a hollow insulator, a primary terminal located on the hollow insulator and connected to the high-voltage power line, first and second capacitors arranged as a voltage divider circuit, one or more primary insertion resistors, and solid dry foam dielectric formed around the first capacitor and the second capacitor within the hollow insulator.

### CROSS-REFERENCE TO RELATED APPLICATIONS

This application claims the benefit of priority under 35 U.S.C. 102(e) to U.S. Provisional Application No. 63/560,207 filed Mar. 1, 2024, the contents of which are hereby incorporated by reference in their entirety.

### FIELD

The present disclosure relates to voltage dividers, and in particular, to resistive capacitive voltage dividers used in the electrical power and distribution industry.

### BACKGROUND

The electrical power grid needs to be monitored at all times to facilitate the safe and continuous supply of electricity. To this end, the ability to detect and respond to problems is paramount. Monitoring requires obtaining current and voltage measurements and using these measurements for monitoring, metering, relaying and remediation throughout the system. As will be appreciated, electrical transmission lines operate at high voltages. These high voltages pose a risk to auxiliary equipment and secondary equipment such as Intelligent Electronic Devices (IED). Accordingly, utility companies have a need to convert high transmission class voltages or step down voltages into lower voltages that may be used for management functions such as measurement, monitoring, relaying control and metering. The lower voltages are also used to control protective relays in the power grid. Successful conversion of high voltage (HV) to a representative low voltage (LV) for use in the management of the power grid is essential.

A high voltage (HV) voltage divider is a device used to step down high transmission line voltages into the lower voltages that are representative and more useful in managing and monitoring the electrical grid. A capacitive voltage transformer (CVT) is a common and cost-effective type of device used by electric utility companies to step down high transmission line voltages to lower voltages. A capacitor coupled voltage transformer (CCVT) is similar to a CVT, but with the addition of a carrier coupling unit that allows the CCVT to couple power line carrier (PLC) signals to a transmission line for communication purposes. The terms CVT and CCVT are often used interchangeably.

FIG. 1 depicts a simplified circuit diagram of a conventional CVT 100. CVT 100 includes capacitors 111 and 113 which are surrounded by a liquid or gaseous dielectric material 101, and the transformer 103. Due to the high voltages being managed, the capacitors in these conventional devices are placed in either porcelain or composite hollow insulators that are filled with a liquid dielectric (e.g., mineral oil) or a gaseous dielectric (e.g., SF6 gas). One drawback of such conventional designs is that they contain environmentally hazardous materials that cause problem if the CVT breaks or wears out and needs to be disposed of. Another drawback is that these conventional CVT voltage dividers may be flammable or even explosible. Moreover, voltage dividers that are filled with gaseous dielectrics may be categorized as pressure vessels, thus requiring compliance with American Society of Engineers (ACME) code. Another drawback in using gaseous SF6 as a dielectric is that it is one of the most potent greenhouse gases on earth, and thus, quite environmentally unfriendly.

Most conventional CVT designs rely on capacitive condensers which tend to be prone to accuracy drift with increasing age. Another drawback of convention CVT dividers is presented by the ever-growing need to accurately access power quality in the modern electrical grid. Accessing power quality requires measuring all of the harmonic levels in the system. Convention CVTs of the type described above are unable to account for harmonics in the system without the use of peripheral equipment. Accordingly, there remains a need in the art for a CVT that measures the harmonics that convention CVTs cannot.

### SUMMARY

Various embodiments disclosed herein that are advantageous over the conventional voltage dividers currently in use in the power transmission and distribution industry. For example, various embodiment may be implemented as a newly designed geometry graded electrode systems containing a solid dielectric material. Various embodiments of the solid dielectric are advantageous in that they deter leakages and typically do not require replenishment of the dielectric media. Some embodiments may be implemented with nonflammable (and nonexplosive) types of solid dielectric material. The various embodiments implemented as a straightforward geometry grading system are relatively inexpensive to manufacture. The various embodiments are also versatile inasmuch as they may be expandable as a capacitive-resistive dividers (CR dividers). The embodiments are also advantageous in that the dry solid foam or solid gel dielectric material flows in and around the internal components of the voltage divider and then solidifies, enhancing structural support.

Various embodiments provide a capacitive voltage divider apparatus configured to step down a high-voltage from an electrical power line to a low-voltage. The apparatus includes solid dielectric material, a hollow insulator with a distal end and a proximal end, the hollow insulator containing at least some of the solid dielectric material. The apparatus also includes a primary terminal positioned at the distal end of the hollow insulator, the primary terminal being configured for an electrical connection to a conductor at the high-voltage of the electrical power line. A high voltage electrode of the apparatus is within and surrounded by the solid dielectric material. The apparatus also includes a high voltage lead that electrically connects the primary terminal to the high voltage electrode. The high voltage lead is at least partially within the solid dielectric material. The apparatus also includes voltage divider circuitry within the solid dielectric material and a shield component included as part of the voltage divider circuitry. The shield component is in proximity to the high voltage electrode, and the shield component is within and surrounded by the solid dielectric material.

In some embodiments of the capacitive voltage divider apparatus include first and second portions of the solid dielectric material. The capacitive voltage divider may also include a component container affixed to the proximal end of the hollow insulator. The voltage divider circuitry and second portion of the solid dielectric material may be contained within the component container. In some embodiments of the capacitive voltage divider the component container is a CVT tank, and the voltage divider circuitry and dielectric material are contained within the CVT tank. In such embodiments the voltage divider circuitry is within and surrounded by the second portion of the solid dielectric material.

Some embodiments of the capacitive voltage divider apparatus include first and second capacitors positioned within and surrounded by the second portion of the solid dielectric material. The first capacitor includes a first lead and a second lead, and the second capacitor includes a third lead and a fourth lead. The second lead is electrically connected to the third lead. In some embodiments of the capacitive voltage divider apparatus the voltage divider circuitry is an axial grading capacitive voltage divider.

In some embodiments of the capacitive voltage divider apparatus the shield component is a calotte shield with the first lead of the first capacitor is electrically connected to the calotte shield and the fourth lead of the second capacitor is connected to a ground potential. Some embodiments include a terminal box which has a first terminal electrically connected to the second lead of the first capacitor and a ground terminal electrically connected to ground potential.

In some embodiments the high voltage lead includes a first high voltage lead section with a first end and a second end. The first end is electrically connected to the primary terminal. The high voltage lead may have a second high voltage lead section with a third end and a fourth end.

Some embodiments include a primary insertion resistor that is electrically connected between the second end of the first high voltage lead section and the third end of the second high voltage lead section. The fourth end of the second high voltage lead section may be electrically connected to the high voltage electrode. In various embodiments the high-voltage is at least 7,000 volts and the low-voltage is no greater than 500 volts.

Various embodiments provide a voltage divider apparatus configured to step down a high-voltage from an electrical power line to a low-voltage. The apparatus may include solid dielectric material, a hollow insulator with a distal end and a proximal end, and containing at least some of the solid dielectric material. The apparatus further includes a primary terminal positioned at the distal end of the hollow insulator. The primary terminal is configured for an electrical connection to a conductor at the high-voltage of the electrical power line. The apparatus also includes a high voltage electrode within and surrounded by the solid dielectric material, and a high voltage lead that electrically connects the primary terminal to the high voltage electrode. The high voltage lead is at least partially within the solid dielectric material. The apparatus also includes voltage divider circuitry within the solid dielectric material, and a cylindrical shield component included as part of the voltage divider circuitry. The cylindrical shield component is in proximity to the high voltage electrode and is within and surrounded by the solid dielectric material.

In various embodiments of the voltage divider apparatus the solid dielectric material includes a first portion and a second portion. Some embodiments also include a component container affixed to the proximal end of the hollow insulator. In some embodiments the voltage divider circuitry and a second portion of the solid dielectric material are contained within the component container.

In some embodiments the component container is a CVT tank. The voltage divider circuitry and dielectric material are contained within the CVT tank, within and surrounded by the second portion of the solid dielectric material. In some embodiments the high voltage electrode has a cylindrical section, and the voltage divider circuitry further includes a coaxial ground cylinder electrode electrically connected to ground potential. In some embodiments the high voltage electrode, the cylindrical shield component and the coaxial ground cylinder are concentric. The high voltage electrode is positioned within the cylindrical shield component, and the cylindrical shield component is positioned within the coaxial ground cylinder. In various embodiments the voltage divider circuitry is a radial geometry grading capacitive voltage divider. Some embodiments include a terminal box mounted on an outside surface of the component container. A first terminal within the terminal box is electrically connected to the cylindrical shield component, and a ground terminal within the terminal box is electrically connected to the ground potential. In some embodiments the high-voltage is at least 7,000 volts and the low-voltage is no greater than 500 volts.

### BRIEF DESCRIPTION OF THE DRAWINGS

Various aspects and advantageous features of the present disclosure will become more apparent to those of ordinary skill in the art from the explanations in the Detailed Description below, and reference to the accompanying drawings, wherein:

FIG. 1 depicts a circuit diagram of a conventional capacitive voltage divider (CVT) filled with liquid or gaseous dielectric material.

FIGS. 2A-B depict cross-sectional views of axial geometry grading capacitive voltage dividers in accordance with various embodiments disclosed herein.

FIGS. 2C-D depict cross-sectional views of radial geometry grading capacitive voltage dividers in accordance with various embodiments disclosed herein.

### DETAILED DESCRIPTION

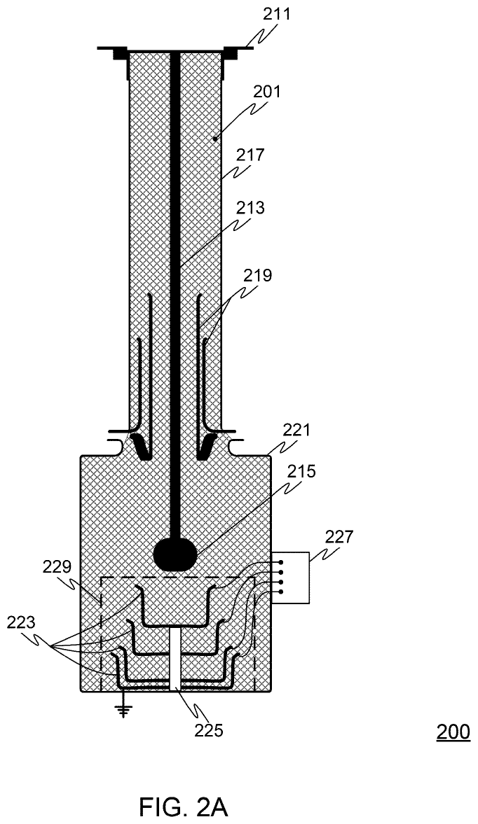

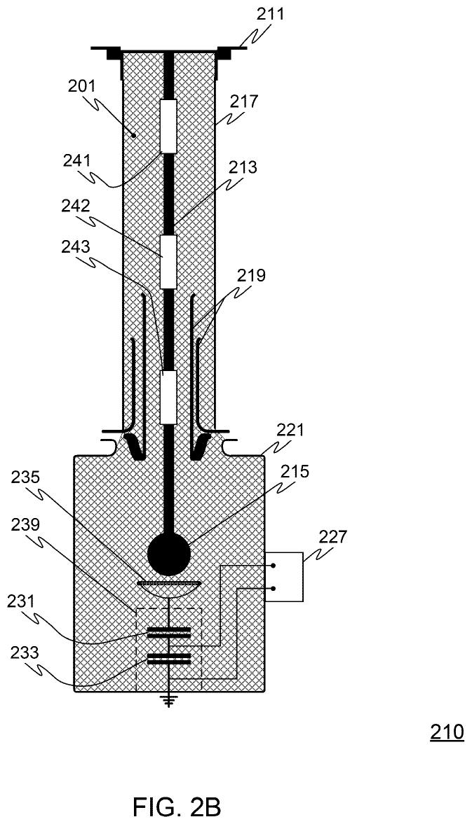

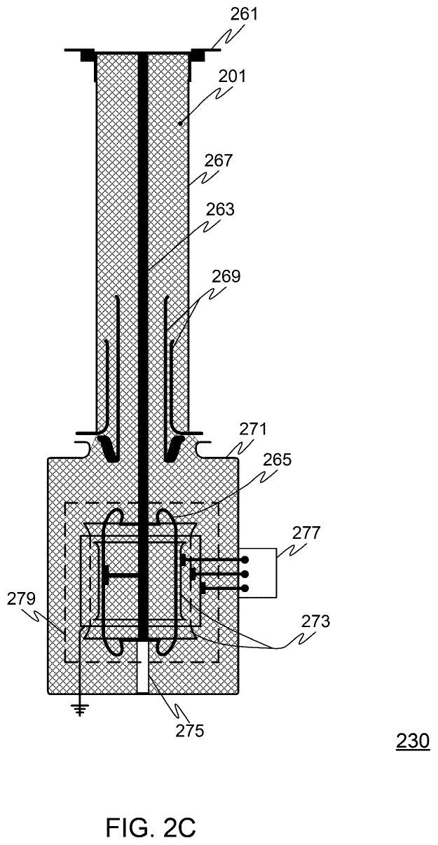

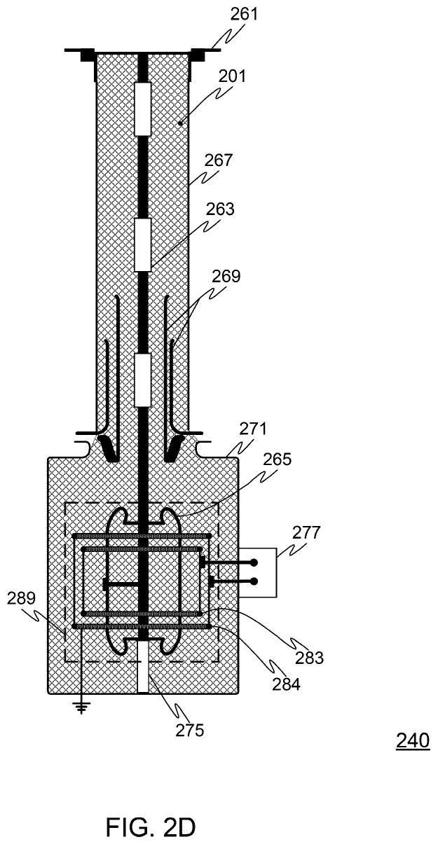

Presently preferred embodiments of the present disclosure illustrating a capacitive voltage divider for use in the power industry is depicted in FIGS. 2A-D. While the description of these embodiments is set forth in connection with a CVT for use in the power industry whether in generation, substations, renewables, or other areas where an LV signal representative of an HV signal is needed, one of ordinary skill in the art will readily appreciate that the advantageous features described herein may be used in any field or environment where an independent measurement of an HV signal is needed.

FIGS. 2A and 2B are cross-sectional views depicting implementations 200 and 210 of axial geometry grading capacitive voltage dividers with solid dielectric material 201 in accordance with various embodiments disclosed herein. Use of the solid dielectric material 201 in the various embodiments eliminates the need for gaseous or liquid dielectrics thus overcoming the disadvantages of conventional gaseous or liquid dielectrics—e.g., dielectric leakage, environmental hazards, and in some cases, flammability or explosiveness. Further, the use of a straight-forward electrode-based grading system in the various embodiments avoids the need for capacitive condensers which are a source of inaccuracy in conventional voltage dividers.

In various embodiments the solid dielectric material 201 may be implemented as a solid dry foam dielectric or may be a solidified gel dielectric. In some of the various embodiments the solid dielectric material 201 may be rigid like extruded polystyrene (e.g., Styrofoam™) or more flexible like a silicone rubber compound that cures into a solidified dielectric silicone gel. Two suitable dielectrics are Wacker SilGel™ and Dow SYLGARD™ 527 solid Silicone Dielectric Gel. In other implementations the solid dielectric material 201 may be flexible like extruded polyethylene (e.g., flexible packing foam sheets).

Turning to FIG. 2A, the axial grading capacitive voltage divider implementation 200 has a high voltage primary terminal 211 which may be electrically connected to a high voltage source such as a high voltage electrical transmission or distribution line. A high voltage lead 213 runs through a hollow insulator 217, connecting the high voltage primary terminal 211 to high voltage electrode 215. The hollow insulator 217 may be made from an insulative composite material, in which case it is called a hollow composite insulator (HCI) 217. In some implementations the hollow insulator 217 may be porcelain or other such insulating material as are known by those of ordinary skill in the art. The hollow insulator 217 has a distal end (top in FIG. 2A) and a proximal end (bottom). The high voltage lead 213 also runs through concentric inner and outer HCI shields 219 contained within the hollow composite insulator 217. The inner and outer HCI shields 219 shields aid in preventing the effects of high field gradients within the device due to the high voltages, and also provide shielding of stray capacitances.

The hollow composite insulator 217 sits on top of CVT tank 221. The CVT tank 221 is a component container that contains voltage divider circuitry 229, an axial grading capacitive voltage divider. The CVT tank 221 may be made from aluminum, a composite material, iron, stainless steel, or other such material that is of sufficient sturdiness to support the hollow composite insulator 217. The high voltage lead 213 extends into CVT tank 221. A high voltage electrode 215 is at the end of high voltage lead 213. The CVT tank 221 is typically filled with the solid dielectric material 201. The dielectric material 201 is flowed into CVT tank 221 as a liquid, and then solidifies into solid dielectric material 201. This results in the components of voltage divider circuitry 229 being within and surrounded by the solid dielectric material 201. Once it is solidified the solid dielectric material 201 adheres to the surfaces of the components of voltage divider circuitry 229. The hollow composite insulator 217 taken together with CVT tank 221 may, in some instances, be considered to be a single container that holds the solid dielectric material 201. CVT tank 221 of FIG. 2A contains a number of grading shields 223 which are part of the voltage divider circuitry 229. The grading shields 223 are supported by a supporting insulator 225 affixed to the bottom of CVT tank 221. A terminal box 227 is connected on the outside of CVT tank 221. The terminal box 227 contains terminals that are electrically connected to the various grading shields 223, providing access to the stepped down voltages.

Conventional CVTs contain dielectrics in liquid or gaseous form such as mineral oil or SF6. The conventional liquid/gaseous dielectrics flow freely within the CVT container, surrounding all the internal components of the voltage divider. The various embodiments have this same advantageous feature since the dielectric material 201 is flowed in (or forced in) in liquid form, surrounding all the internal components of capacitive voltage divider 200. The dielectric material 201 solidifies as it cools, forming a dry foam (or solid gel) dielectric that surrounds the internal components of capacitive voltage divider 200. The solid dielectric material 201 of the various embodiments is advantageous over conventional liquid/gaseous dielectrics in that it solidifies around and clings to the internal components, providing some structural support. The added structural support aids in preserving the structural integrity of the capacitive voltage divider 200 as it experiences vibrations and movement due to wind, traffic, trains, earthquakes, or other outside influences.

FIG. 2B depicts a cross-sectional view of an axial geometry grading capacitive voltage divider implementation 210 in accordance with various embodiments. FIG. 2B is similar to the voltage divider shown in FIG. 2A, but with the addition of high voltage (HV) primary insertion resistors 241-243 and substitution of medium voltage secondary voltage divider circuitry 239. The axial grading capacitive voltage divider 210 has a high voltage primary terminal 211 which may be electrically connected to a high voltage source such as a high voltage electrical transmission or distribution line. Segments of high voltage lead 213 electrically connect the components of axial grading capacitive voltage divider 210 within the hollow insulator 217. HV primary insertion resistors 241-243 are connected in series between the high voltage primary terminal 211 and the high voltage electrode 215. Three HV primary insertion resistors are shown in FIG. 2B. However, the device may be implemented with more or fewer high voltage primary insertion resistors, depending upon the requirements of the installation and availability or cost of components. The insertion of HV primary insertion resistors 241-243 makes axial grading capacitive voltage divider 210 suitable for very high harmonics transients. The addition of the HV primary insertion resistors 241-243 makes the arrangement of the components similar to a Zaengl voltage divider, sometimes called a series-damped capacitive divider. However, prior to the present invention no Zaengl voltage divider design has been implemented with a solid dielectric as are the various embodiments disclosed herein.

The hollow insulator 217 may be made from an insulative composite material, in which case it is called a hollow composite insulator (HCI) 217. In some implementations the hollow insulator 217 may be porcelain or other such insulating material as are known by those of ordinary skill in the art. The hollow insulator 217 has a distal end, towards the top of the figure, and a proximal end towards the bottom of the figure. The high voltage lead 213 and/or one or more of the HV primary insertion resistors 241-243 run through concentric inner and outer HCI shields 219 contained within the hollow composite insulator 217. The inner and outer HCI shields 219 shields aid in preventing the effects of high field gradients within the device due to the high voltages, and also provide shielding of stray capacitances.

The hollow composite insulator 217 sits on top of CVT tank 221 which contains the medium voltage (MV) secondary voltage divider circuitry 239. The CVT tank 221 may be made from aluminum, a composite material, iron, stainless steel, or other such material that is of sufficient sturdiness to support the hollow composite insulator 217. The high voltage lead 213 extends into CVT tank 221. A high voltage electrode 215 is positioned at the end of high voltage lead 213 in proximity to calotte shield 235. This results in a voltage V1 at calotte shield 235. The high voltage electrode 215 may be spherical in shape, or may be implemented with oval or otherwise rounded cross-section, depending upon the shape of calotte shield 235. The CVT tank 221 is typically filled with the solid dielectric material 201. The dielectric material 201 is flowed into CVT tank 221 as a liquid, and then solidifies into solid dielectric material 201. This results in the components of voltage divider circuitry 239 being within and surrounded by the solid dielectric material 201. Once it is solidified the solid dielectric material 201 adheres to the surfaces of the components of voltage divider circuitry 239. The hollow composite insulator 217 taken together with CVT tank 221 may be considered to be a single container that holds the solid dielectric material 201.

CVT tank 221 of FIG. 2B contains medium voltage (MV) secondary voltage divider circuitry 239. The C1 capacitor 231 of the MV secondary voltage divider circuitry 239 is electrically connected between calotte shield 235 and the C2 capacitor 233. The other side of C2 capacitor 233 is electrically connected to ground. This design provides a stepped down voltage terminal, and a ground terminal to terminal box 227. FIG. 2 depicts two capacitors 231/233. However, in practice the MV secondary voltage divider circuitry 239 may be implemented with more capacitors so as to provide more voltage terminals within terminal box 227 at various stepped down voltages.

The C1 capacitor 231 and C2 capacitor 233 are in series between the voltage V1 at calotte shield 235 and ground. Capacitors C1 and C2 are shown as two capacitors in the simplified circuit diagram of FIG. 2B. However, in practice C2 (and sometimes C1) may itself be embodied as multiple capacitors in parallel or in a circuit configuration of parallel and/or series capacitors. For example, C2 may consist of multiple capacitors C3+C4+C5 in parallel (not shown).

The MV secondary voltage divider circuitry 239 steps down the voltage V1 at calotte shield 235 to a useable lower voltage V2 which is routed to the terminal box 227. The terminal box 227 contains a terminal that is electrically connected to between the capacitors C1 and C2 and another terminal at ground potential, providing access to the stepped down voltage from MV secondary voltage divider circuitry 239. To step down the relatively high voltage V1 to a lower, useable voltage V2 the capacitor C2 must typically be much larger than capacitor C1. The lower voltage V2 is a ratio of the capacitance values of C1 and C2 applied to the higher voltage V1 as follows:

$$V 2 = V 1 \times C 1 / ( C 1 + C 2 )$$

The solid dielectric material 201 is shown surrounding both C1 and C2. In some implementations, however, the C1 and C2 capacitors may be contained in different containers or different compartments of the CVT tank 221. This allows the C1 and C2 capacitors to be packed in different types of the solid dielectric material 201. Depending upon the expected requirements and conditions of the CVT, the solid dry foam dielectric 101 may be implemented in various degrees of hardness/flexibility.

FIG. 2C depicts a cross-sectional view of radial geometry grading capacitive voltage divider implementation 220 in accordance with various embodiments disclosed herein. The radial geometry grading capacitive voltage divider 220 has a high voltage primary terminal 261 at voltage V1 which may be electrically connected to a high voltage source such as a high voltage electrical transmission or distribution line. A high voltage lead 263 runs through a hollow insulator 267, connecting the high voltage primary terminal 261 to high voltage electrode 265 which is also at voltage V1. The high voltage electrode 265 typically is cylindrically shaped, or as in FIG. 2C (and FIG. 2D), has a cylindrically shaped section with tapered ends.

The hollow insulator 267 may be made from an insulative composite material, or porcelain, or another such insulating material as are known by those of ordinary skill in the art. The hollow insulator 267 has a distal end (top in FIG. 2C) and a proximal end (bottom). The high voltage lead 263 also runs through concentric inner and outer HCI shields 269 contained within the hollow composite insulator 267. The inner and outer HCI shields 269 shields aid in preventing the effects of high field gradients within the device due to the high voltages, and also provide shielding of stray capacitances.

The hollow composite insulator 267 sits on top of CVT tank 271. The CVT tank 271 is a component container that contains the voltage divider circuitry 279, a radial geometry grading capacitive voltage divider. The CVT tank 271 may be made from aluminum, a composite material, iron, stainless steel, or other such material that is of sufficient sturdiness to support the hollow composite insulator 267. The high voltage lead 263 extends into CVT tank 271, connecting to high voltage electrode 265. The CVT tank 271 is typically filled with solid dielectric material 201. The dielectric material 201 is flowed into CVT tank 271 as a liquid, and then solidifies into solid dielectric material 201. This results in the components of voltage divider circuitry 279 being within and surrounded by the solid dielectric material 201. Once it is solidified the solid dielectric material 201 adheres to the surfaces of the components of voltage divider circuitry 279. The hollow composite insulator 267 taken together with CVT tank 271 may be considered to be a single container that holds the solid dielectric material 201. CVT tank 271 contains two grading shields 273 and a ground screening shield 274 (sometimes called guard electrode) which are part of the voltage divider circuitry 279. The grading shields 273 and ground screening shield 274 are supported by a supporting insulator 275 affixed to the bottom of CVT tank 271. A terminal box 277 is connected on the outside of CVT tank 271. The terminal box 277 contains terminals V2, V3 and GND that are electrically connected to the grading shields 273 and the ground screening shield 274, providing access to the stepped down voltages.

FIG. 2D depicts a cross-sectional view of radial geometry grading capacitive voltage divider implementation 230 in accordance with various embodiments disclosed herein. The radial geometry grading capacitive voltage divider 230 has a high voltage primary terminal 261 at voltage V1 which may be electrically connected to a high voltage source such as a high voltage electrical transmission or distribution line. Segments of high voltage lead 213 electrically connect the components of radial geometry grading capacitive voltage divider 230 within the hollow insulator 267. High voltage (HV) primary insertion resistors 241-243 are connected in series between the high voltage primary terminal 211 and the high voltage electrode 265. Three HV primary insertion resistors are shown in FIG. 2D. However, the device may be implemented with more or fewer high voltage primary insertion resistors, depending upon the requirements of the installation and availability or cost of components. The insertion of HV primary insertion resistors 241-243 makes radial geometry grading capacitive voltage divider 230 suitable for very high harmonics transients.

The hollow insulator 267 has a distal end, towards the top of the figure, and a proximal end towards the bottom of the figure. The high voltage lead 213 and/or one or more of the HV primary insertion resistors 241-243 run through concentric inner and outer HCI shields 219 contained within the hollow composite insulator 267. The inner and outer HCI shields 219 shields aid in preventing the effects of high field gradients within the device due to the high voltages, and also provide shielding of stray capacitances. The inner and outer HCI shields 269 shields aid in preventing the effects of high field gradients within the device due to the high voltages, and also provide shielding of stray capacitances.

The hollow composite insulator 267 sits on top of CVT tank 271. The CVT tank 271 is a component container that contains the components of the secondary voltage divider circuitry 289, a radial geometry grading capacitive voltage divider. The CVT tank 271 may be made from aluminum, a composite material, iron, stainless steel, or other such material that is of sufficient sturdiness to support the hollow composite insulator 267. The high voltage lead 263 extends into CVT tank 271, connecting to high voltage electrode 265. The CVT tank 271 is typically filled with the solid dielectric material 201. The dielectric material 201 is flowed into CVT tank 271 as a liquid, and then solidifies into solid dielectric material 201. This results in the components of voltage divider circuitry 289 being within and surrounded by the solid dielectric material 201. Once it is solidified the solid dielectric material 201 adheres to the surfaces of the components of voltage divider circuitry 289. The hollow composite insulator 267 taken together with CVT tank 271 may be considered to be a single container that holds the solid dielectric material 201. CVT tank 271 contains a HV coaxial cylindrical electrode 265, a coaxial tap electrode 283 and a coaxial ground cylinder electrode 284 (sometimes called guard electrode) which are part of secondary voltage divider circuitry 289. The coaxial tap electrode 283 and coaxial ground cylinder electrode 284 are at least partly cylindrical. In some implementations the coaxial tap electrode 283 and coaxial ground cylinder electrode 284 may have a cylindrical center section with flared ends. The HV coaxial cylindrical electrode 265, coaxial tap electrode 283 and coaxial ground cylinder electrode 284 are supported by a supporting insulator 275 affixed to the bottom of CVT tank 271. A terminal box 277 is connected on the outside of CVT tank 271. Terminal box 277 contains terminals V2 and GND that are electrically connected to the coaxial tap electrode 283 and coaxial ground cylinder electrode 284, providing access to the stepped down voltages.

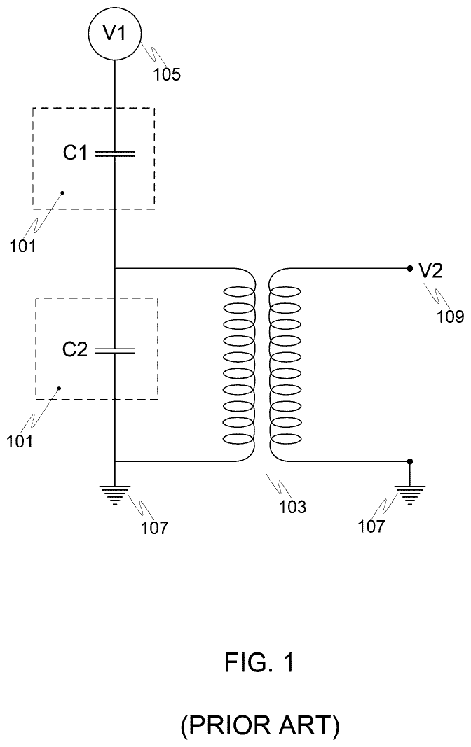

The term “electrically connected” as used herein means that two components are connected by an electrically conductive path, i.e., galvanically connected. In some implementations a component may be electrically connected to another component via one or more other components so that current flows between the components and/or the voltage of one component is affected by the other component. For example, the bottom lead of capacitor C2 of FIG. 1 may be connected to the grounded terminal of transformer 103, which in turn, is connected to ground. In another example, the top lead of C2 (which connects to C1) may be connected to transformer 103 via compensating reactor circuitry designed to compensate for the phase shift caused by the capacitive voltage divider formed by C1 and C2. Two components may be “directly electrically connected”, in which case they are connected to each other rather than being connected via a third component.

As described above, the present disclosure provides embodiments of a capacitive voltage divider that does not pose an environmental risk from the use of gaseous or liquid insulants and/or a risk of shattering from use of a porcelain vessel under pressure. The present disclosure also provides embodiments of a capacitive voltage divider having a simple metallic electrode-based grading system and avoids capacitive condensers that are prone to accuracy drift with increasing age. Further, as described above, various of the above and other embodiments of the present disclosure provide a capacitive voltage divider with improve power quality monitoring.

One of ordinary skill will appreciate that the exact dimensions and materials are not critical to the disclosure and all suitable variations should be deemed to be within the scope of the disclosure if deemed suitable for carrying out the objects of the disclosure. One of ordinary skill in the art will also readily appreciate that it is well within the ability of the ordinarily skilled artisan to modify one or more of the constituent parts for carrying out the various embodiments of the disclosure. Once armed with the present specification, routine experimentation is all that is needed to determine adjustments and modifications that will carry out the present disclosure.

In the various embodiments components are said to be within and surrounded by the solid dielectric material. A component that is “within and surrounded by” another material is engulfed by it on all sides. In some cases the dielectric material may adhere to the surfaces of the component, and in other instances it may not. For example, a person underwater in a swimming pool is within and surrounded by the water, but the liquid water does not adhere to the person. The components of a voltage divider are within and surrounded by a solid foam dielectric if the foam dielectric is flowed in and around the components as a liquid and then solidifies. Also, once it is solidified the solid foam dielectric adheres to the voltage divider components. A component wrapped in or layered in solid sheets of dielectric material is not within and surrounded by the sheets of dielectric material.

The embodiments described above are for illustrative purposes and are not intended to limit the scope of the disclosure or the adaptation of the features described herein to particular optical voltage sensing systems or electro-optic crystal assemblies. Those skilled in the art will also appreciate that various adaptations and modifications of the above-described preferred embodiments can be configured without departing from the scope and spirit of the disclosure. Therefore, it is to be understood that, within the scope of the appended claims, the invention may be practiced other than as specifically described.

What is claimed is:

1. A capacitive voltage divider apparatus configured to step down a high-voltage from an electrical power line to a low-voltage, the apparatus comprising:
solid dielectric material;
a hollow insulator with a distal end and a proximal end, the hollow insulator containing at least some of the solid dielectric material;
a primary terminal positioned at the distal end of the hollow insulator, the primary terminal being configured for an electrical connection to a conductor at the high-voltage of the electrical power line;
a high voltage electrode within and surrounded by the solid dielectric material;
a high voltage lead that electrically connects the primary terminal to the high voltage electrode, the high voltage lead at least partially within the solid dielectric material;
voltage divider circuitry within the solid dielectric material; and
a shield component included as part of the voltage divider circuitry, the shield component being in proximity to the high voltage electrode, wherein the shield component is within and surrounded by the solid dielectric material.

2. The capacitive voltage divider apparatus of claim 1, wherein the at least some of the solid dielectric material is a first portion of the solid dielectric material, the capacitive voltage divider further comprising:
a component container affixed to the proximal end of the hollow insulator;
wherein the voltage divider circuitry and a second portion of the solid dielectric material are contained within the component container.

3. The capacitive voltage divider apparatus of claim 2,
wherein the component container is a CVT tank;
wherein the voltage divider circuitry and dielectric material are contained within the CVT tank; and
wherein the voltage divider circuitry is within and surrounded by the second portion of the solid dielectric material.

4. The capacitive voltage divider apparatus of claim 2, wherein the voltage divider circuitry comprises:
a first capacitor positioned within and surrounded by the second portion of the solid dielectric material, the first capacitor including a first lead and a second lead; and
a second capacitor positioned within and surrounded by the second portion of the solid dielectric material, the second capacitor including a third lead and a fourth lead;
wherein the second lead is electrically connected to the third lead.

5. The capacitive voltage divider apparatus of claim 1, wherein the voltage divider circuitry is an axial grading capacitive voltage divider.

6. The capacitive voltage divider apparatus of claim 4,
wherein the shield component is a calotte shield; and
wherein the first lead of the first capacitor is electrically connected to the calotte shield and the fourth lead of the second capacitor is connected to a ground potential.

7. The capacitive voltage divider apparatus of claim 6, further comprising:
a terminal box;
a first terminal within the terminal box electrically connected to the second lead of the first capacitor; and
a ground terminal within the terminal box electrically connected to the ground potential.

8. The capacitive voltage divider apparatus of claim 1,
wherein the high voltage lead comprises a first high voltage lead section with a first end and a second end, the first end being electrically connected to the primary terminal; and
wherein the high voltage lead comprises a second high voltage lead section with a third end and a fourth end.

9. The capacitive voltage divider apparatus of claim 8, further comprising:
a primary insertion resistor electrically connected between the second end of the first high voltage lead section and the third end of the second high voltage lead section;
wherein the fourth end of the second high voltage lead section is electrically connected to the high voltage electrode.

10. The capacitive voltage divider apparatus of claim 9, wherein the high-voltage is at least 7,000 volts and the low-voltage is no greater than 500 volts.

11. A voltage divider apparatus configured to step down a high-voltage from an electrical power line to a low-voltage, the apparatus comprising:
solid dielectric material;
a hollow insulator with a distal end and a proximal end, the hollow insulator containing at least some of the solid dielectric material;
a primary terminal positioned at the distal end of the hollow insulator, the primary terminal being configured for an electrical connection to a conductor at the high-voltage of the electrical power line;
a high voltage electrode within and surrounded by the solid dielectric material;
a high voltage lead that electrically connects the primary terminal to the high voltage electrode, the high voltage lead at least partially within the solid dielectric material;
voltage divider circuitry within the solid dielectric material; and
a cylindrical shield component included as part of the voltage divider circuitry, the cylindrical shield component being in proximity to the high voltage electrode, wherein the cylindrical shield component is within and surrounded by the solid dielectric material.

12. The voltage divider apparatus of claim 11, wherein the at least some of the solid dielectric material is a first portion of the solid dielectric material, the capacitive voltage divider further comprising:
a component container affixed to the proximal end of the hollow insulator;
wherein the voltage divider circuitry and a second portion of the solid dielectric material are contained within the component container.

13. The voltage divider apparatus of claim 12,
wherein the component container is a CVT tank;
wherein the voltage divider circuitry and dielectric material are contained within the CVT tank; and
wherein the voltage divider circuitry is within and surrounded by the second portion of the solid dielectric material.

14. The voltage divider apparatus of claim 12, wherein the high voltage electrode has a cylindrical section, and wherein the voltage divider circuitry further comprises:
a coaxial ground cylinder electrode electrically connected to ground potential.

15. The voltage divider apparatus of claim 14,
wherein the high voltage electrode, the cylindrical shield component and the coaxial ground cylinder are concentric.

16. The voltage divider apparatus of claim 15,
wherein the high voltage electrode is positioned within the cylindrical shield component, and the cylindrical shield component is positioned within the coaxial ground cylinder.

17. The voltage divider apparatus of claim 16, wherein the voltage divider circuitry is a radial geometry grading capacitive voltage divider.

18. The voltage divider apparatus of claim 17, further comprising:
a terminal box mounted on an outside surface of the component container.

19. The voltage divider apparatus of claim 18, further comprising:
a first terminal within the terminal box electrically connected to the cylindrical shield component; and
a ground terminal within the terminal box electrically connected to the ground potential.

20. The voltage divider apparatus of claim 19, wherein the high-voltage is at least 7,000 volts and the low-voltage is no greater than 500 volts.
